(19) United States
(12) Patent Application Publication
(10) Pub. No.: US 2009/0219701 A1
(43) Pub. Date: Sep. 3, 2009

(54) SLIDING FLAT PANEL DISPLAY AND KEYBOARD MODULE

(76) Inventors: Sui-An Wu, Keelung City (TW); You-Lin Shih, Sindian City (TW)

Correspondence Address: Patterson & Sheridan, LLP, Suite 100, 595 Shrewsbury Avenue, Shrewsbury, NJ, 07702, US

(21) Appl. No.: 12/325,338

(22) Filed: Dec. 1, 2008

Related U.S. Application Data
(60) Provisional application No. 61/032,752, filed on Feb. 29, 2008.

(51) Int. Cl. H05K 7/14

(52) U.S. Cl. 361/727

(57) ABSTRACT

Embodiments for a slider mounting module suitable for mounting a KVM assembly to a server rack are provided. In one embodiment, the slider mounting module includes a front rack mount and a back rack mount which are configured to couple together and be secured to a server rack. The coupling of the front rack mount to the back rack mount is adjustable to accommodate different depth server racks. The slider mounting module includes a front move plate slidably coupled to the front rack mount and a back move plate slidably coupled to the back rack mount. The front and back rack mounts provide a mounting surface for KVM assembly.

### CROSS-REFERENCE TO RELATED APPLICATIONS

This application claims benefit of U.S. Provisional Application Ser. No. 61/032,752 filed Feb. 29, 2008 (Attorney Docket No. ATEN/P97002L), which is incorporated by reference in its entirety.

### BACKGROUND

1. Field of the Invention

Embodiments of the present invention generally relate to a sliding flat panel display and keyboard module. More particularly, the embodiments of the invention generally relate to a sliding flat panel display and keyboard module for a rack-mounted KVM switch.

2. Description of the Related Art

Information technology and the computer industry are highly developed now. People rely heavily on computer systems. Therefore, computer servers with high calculation capacity and high stability are important for computer systems. Due to increasingly reduced office space, area occupied by computer servers must also be reduced. Computer servers must maintain a high degree of stability to serve users, and the space occupied by one computer server is therefore greater than or equal to that of a desktop computer. Accordingly, the management of computer servers is difficult and space utilization is at a premium. Some companies have two or three computer servers, while others may have more than a thousand computer servers. Computer server management and space utilization become more critical in companies with more computer servers.

A 1U computer server assembled on a standard 1U server rack is the mainstream computer server arrangement. Each standard layer of the server rack is about 1.75 inches (about 4.5 centimeters), so that the 1U server and the server rack effectively conserve occupational space of the computer servers. Moreover, the 1U servers and racks are more efficiently controlled because the 1U servers and racks can be centrally managed and easily stacked. Normally, hardware used in the 1U server is provided with a smaller size and lower height to fit the thickness limitation of 1.75 inches.

For conveniently controlling the stacked 1U computer servers on the server rack, users utilize KVM switches to connect and control multiple computer servers. Typically, one set of keyboard, video and mouse is included in the KVM switch to selectively operate multiple computer servers coupled to the KVM switch. Hence, the quantity of the displays and keyboards needed for controlling the computer servers can be effectively reduced and the occupied space thereof can also be reduced.

However, due to the height constraints on the 1U server rack, the dimensions of the keyboard and the display have to fulfill dimensional limitations to be incorporated and operate on the server rack. Additionally, even under the dimensional limitations, the keyboard and the display contribute to providing a safe and reliable working environment for users.

Furthermore, the multiple computer servers stacked on the rack may limit the extension and operational space of the keyboard, video and mouse coupled to the KVM switch. For example, as the KVM switch may be stacked in a central position of rack, one or more computer servers may be stacked on the upper selves above the position of the KVM switch. As the upper space of the rack may be occupied by the computer servers, the operational space of keyboard and video display of the KVM switch may be limited by the height constraints of the rack. Therefore, the video display coupled to the KVM switch may not be able to be opened and rotated beyond 90 degrees, thereby limiting the working space and user's viewing angle while operating the video display. In some conventional designs, the space above the KVM switch is empty so that space is reserved for the video display when opened to a vertical operational position, thus resulting in a loss of space which could have been utilized for additional computer servers.

Therefore, there is a need for a slider mounting module for mounting a KVM assembly in a server rack.

### SUMMARY OF THE INVENTION

Embodiments of the invention generally provide a slider mounting module for mounting a KVM assembly in a server rack. The improved slider mounting module may provide a video display coupled to the KVM assembly being able to be opened up to an angle greater than about 95 degrees. In one embodiment, the slider mounting module includes a front rack mount and a back rack mount which are configured to couple together and be secured to a server rack. The coupling of the front rack mount to the back rack mount is adjustable to accommodate server racks having different depths. The slider mounting module includes a front move plate slidably coupled to the front rack mount and a back move plate slidably coupled to the back rack mount. The front and back rack mounts provide a mounting surface for the KVM assembly.

In one embodiment, the back rack mount includes a mounting flange and a primary bar. The primary bar further includes a top edge and a bottom edge configured to provide a bearing surface for the front rack mount coupled thereto. The primary bar further includes a slot configured to couple the back move plate to the back rack mount.

In one embodiment, the front rack mount further includes a mounting flange and a secondary bar, wherein the secondary bar further comprises one or more retaining features. The retaining feature is configured to retain the back rack mount and the front rack mount is a substantially aligned orientation. The secondary bar further includes a second slot formed through the secondary bar and aligned with a first slot formed in a primary bar in the back rack mount. The front move plate engages a first end of a KVM switch system and the back move plate engages a second end of the KVM switch system.

In one embodiment, the front rack mount is in an extended position relative to the front rack mount.

In one embodiment, the slider mounting module further includes a lock assembly coupled to the front rack mount configured to selectively retain the front move plate from moving relative to the front rack mount. The lock assembly further includes a plunger biased toward the front move plate, and a lever operable to move the plunger against the bias. The lock assembly further includes a knob and a plunger mounted to a bracket, wherein the bracket is coupled to the front rack mount.

In one embodiment, the slider mounting module further includes a middle move plate movably coupled to the back rack mount. The back move plate is coupled to the back rack mount by a bearing assembly.

In another embodiment, a KVM switch system receiving assembly includes a server rack having a front support and a back support, a slider mounting assembly disposed to a space defined by the front and the back support of the server rack, wherein the slider mounting assembly comprises a front rack mount, a back rack mount slidably coupled to the front rack mount in a manner that allows a combined length of the rack mounts to be adjusted, a front move plate slidably coupled to the front rack mount and a back move plate slidably coupled to the back rack mount.

In another embodiment, the front rack mount and the back rack mount are telescopically coupled together.

In another embodiment, the front move plate can move independently relative to the back move plate.

In another embodiment, a KVM assembly having a back move plate that can extend beyond the back rack mount is provided.

In another embodiment, a lock assembly is provided to selectively secure the position of the front move plate in a predefined position relative to the front rack mount.

In another embodiment, a KVM switch system receiving assembly includes a server rack having a front support and a back support, a slider mounting assembly disposed to a space defined by the front and the back support of the server rack, wherein the slider mounting assembly comprises a front rack mount, a back rack mount slidably coupled to the front rack mount in a manner that allows a combined length of the rack mounts to be adjusted, a front move plate slidably coupled to the front rack mount; and a back move plate slidably coupled to the back rack mount.

In one embodiment, the slider mounting assembly further includes a middle move plate movably coupled to the back move plate. The back plate is coupled to the back rack mount by a bearing assembly.

In one embodiment, the KVM switch system receiving assembly further includes a KVM switch system having a first side coupled to the front move plate and a second side coupled to the back move plate. The KVM switch system includes a display portion disposed in the KVM switch system configured to be slidably extended outward from the server rack. The display portion is rotatable to a position having an angle greater than 95 degrees relative to a horizontal place.

In yet another embodiment, a KVM switch system receiving assembly includes a server rack having a front support and a back support, a slider mounting assembly disposed to a space defined by the front and the back support of the server rack, a KVM switch system coupled to the server rack through the slider mounting assembly, wherein the KVM switch system includes a monitor display configured to be extendable outward from the server rack and rotatable to a position having an angle greater than 95 degrees relatively to a horizontal plane.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts an isometric view of one embodiment of a slider mounting module;

FIG. 2 is an exploded isometric view of the slider mounting module of FIG. 1;

FIG. 3 is perspective views of one embodiment of a lock assembly;

FIG. 4 depicts another embodiment of a lock assembly;

FIG. 5 is an isometric view of another embodiment of a slider mounting module;

FIG. 6 is an exploded isometric view of the slider mounting module of FIG. 5;

FIG. 7 is an isometric view of another embodiment of a slider mounting module;

FIG. 8 is an exploded isometric view of the slider mounting module of FIG. 7;

FIGS. 9A-D are schematic views of a sequence for mounting a KVM switch, keyboard and flat panel display to a server rack; and

FIGS. 10A-D are schematic views illustrating operation of one embodiment of a slider mounting module.

It is to be noted, however, that the appended drawings illustrate only typical embodiments of this invention and are therefore not to be considered limiting of its scope, for the invention may admit to other equally effective embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

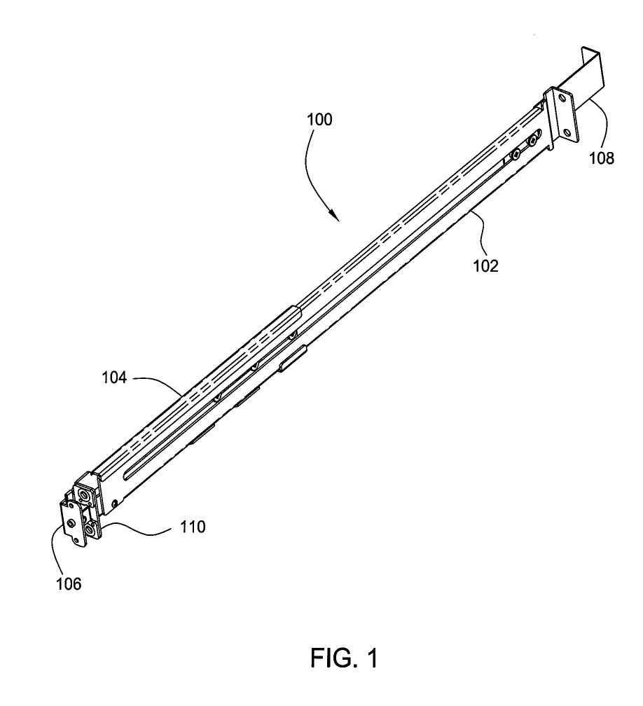

FIG. 1 depicts one embodiment of a slider mounting module 100. The slider mounting module 100 includes a back rack mount 102, a front rack mount 104, a front move plate 106, a back move plate 108 and a lock assembly 110. The front and back rack mounts 104, 102 allows a combined length (not shown) of the front and back rack mounts 104, 102 to be adjusted and mount to a server rack (not shown) to provide the main structural member of the slider mounting module 100. The back move plate 108 is coupled to the back rack mount 102 in a manner that allows the back move plate 108 to slide in the long direction of the back rack mount 102. The front move plate 106 is slidably coupled to the front rack mount 104 in a manner that allows the front move plate 106 to move in a direction aligned with the movement of the back move plate 108. The lock assembly 110 is coupled to the front rack mount 104 and is utilized to secure the front move plate 106 in at least one of an extended or retracted position relative to the front rack mount 104.

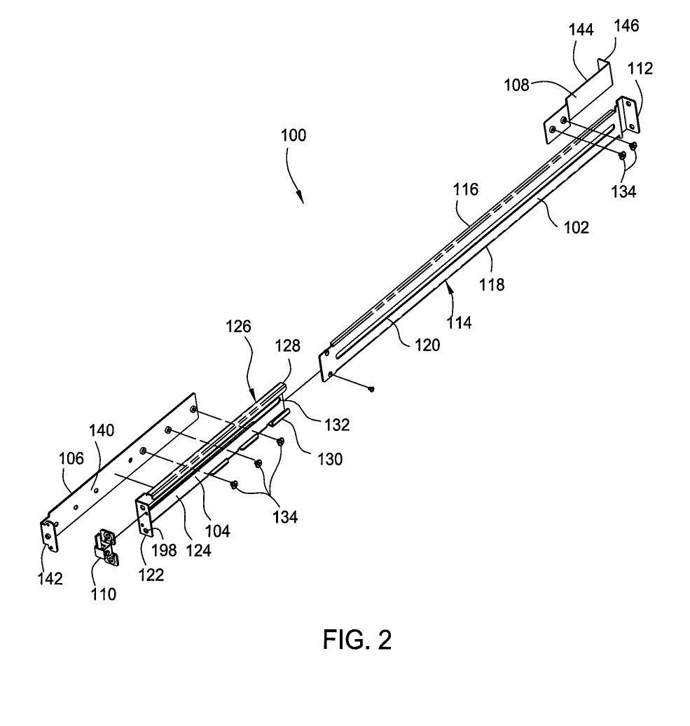

FIG. 2 depicts an exploded view of the slider mounting module 100. The back rack mount 102 includes a mounting flange 112 and a primary bar 114. The mounting flange 112 has an orientation substantially perpendicular to the orientation of the primary bar 114. The mounting flange 112 includes a plurality of holes to facilitate mounting the back rack mount 102 to a rear vertical supports of the server rack. The primary bar 114 generally includes a top edge 116 and a bottom edge 118 which are configured to provide a bearing surface for the front rack mount 104 coupled thereto. In one embodiment, the edges 116, 118 may be rounded, turned over, coated or otherwise prepared to improve the motion of the front rack mount 104 along the primary bar 114.

The primary bar 114 additionally includes a slot 120. The slot 120 facilitates coupling the back move plate 108 to the back rack mount 102. In one embodiment, the back move plate 108 is coupled to the primary bar 114 utilizing a plurality of shoulder screws 134 which pass through the slot 120, thereby facilitating the longitudinal movement of the back move plate 108 along the slot 120. It is contemplated that the shoulder screws 134 may alternatively be a bearing or other element that facilitates movement of the back move plate 108 along the primary bar 114.

In one embodiment, the front rack mount 104 includes a mounting flange 122 coupled to a secondary bar 124. The orientation of the mounting flange 122 is generally perpendicular to the orientation of the secondary bar 124. The mounting flange 122 includes a plurality of mounting holes 198 to facilitate coupling the front rack mount 104 to the front vertical support of the server rack.

The secondary bar 124 generally includes one or more retaining features 126. The retaining feature 126 is configured to retain the back rack mount 102 and the front rack mount 104 aligned in a substantially linear orientation while allowing the front rack mount 104 to be slidably positioned along the primary bar 114 of the back rack mount 102. The adjustable mounting of the front and back rack mounts 104, 102 allows the combined length of the front and back rack mounts 104, 102, such as a distance between the mounting flanges 112, 122, to be selected by the user so that the slider mounting module 100 may be adapted for use with server racks having different depths between the front and back vertical mounting members.

In the embodiment depicted in FIG. 2, the retaining feature 126 includes at least one top channel 128 and at least one bottom channel 130. The top and bottom channels 128, 130 define C-shaped slots which mate with the top and bottom edges 116, 118 of the primary bar 114 of the back rack mount 102, thereby allowing the front rack mount 104 to slide over the back rack mount 102 so that the distance between the rack mounting flanges 112, 122 of the slider mounting module 100 may be telescopically adjusted to accommodate the slider mounting module 100 coupled to the server racks having different depths without modification by the user or the addition of separate components.

The secondary bar 124 additionally includes a slot 132. The slot 132 is formed through the secondary bar 124 such that the slot 132 aligns linearly with the slot 120 of the back rack mount 102. The slot 132 is configured to allow the front move plate 106 to be adjustably attached to the front rack mount 104 so that the position of the front move plate 106 relative to the front rack mount 104 may be selected. In one embodiment, shoulder screws 134 pass through the slot 132 to couple the front move plate 106 to the front rack mount 104, thereby facilitating the longitudinal movement of the front move plate 106 along the slot 132. It is contemplated that the shoulder screws 134 may alternatively be a bearing or other element that facilitates movement of the front move plate 106 along the secondary bar 124.

The front move plate 106 generally includes a bar 140 having a flange 142. The flange 142 is generally orientated perpendicular to the orientation of the bar 140. The flange 142 is configured to engage the front end of a sliding flat panel display (not shown) and a keyboard module (not shown) of a KVM system (not shown), as further described below.

The back move plate 108 includes a bar 144 and a flange 146. The orientation of the flange 146 is generally perpendicular to the orientation of the bar 144. The flange 146 may include one or more mounting holes to facilitate supporting the rear end of the sliding flat panel display and the keyboard module, such as a KVM assembly as further described below. Since the position of the back move plate 108 is decoupled from the position of the front move plate 106, the distance between the move plates 108, 106 may be adjusted to accommodate different size keyboards and display modules.

The lock assembly 110 may be coupled to the front rack mount 104. The lock assembly 110 is configured to selectively engage the front move plate 106 so that the front move plate 106 may be retained in a desired position. The lock assembly 100 is configured to selectively retain the front move plate 106 from moving relative to the front rack mount 104.

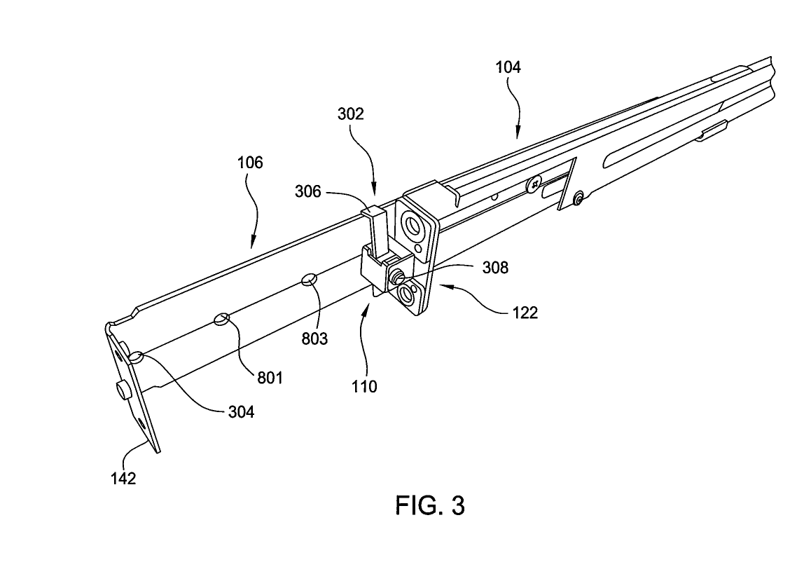

FIG. 3 depicts one embodiment of the lock assembly 110. In one embodiment, the locking assembly 110 is in a form of a spring loaded mechanism 302 which is coupled to the flange 122 of the front rack mount 104. The spring loaded mechanism 302 is biased to selectively engage one or more holes formed through the front move plate 106. Three holes 304, 801, 803 are exemplified in FIG. 3. In the embodiment depicted in FIG. 3, the hole 304 is shown proximate the flange 142 of the front move plate 106, such that the front move plate 106 may be secured in a retracted position relative to the front rack mount 104. It is contemplated that holes 801, 803 may be formed through the front move plate 106, such that the extension of the flange 142 relative to the front rack mount 104 may be secured in other desired positions. The use of the holes 801, 803 will be illustrated more detail hereinafter. In one embodiment, at least one hole 801 or hole 803 is provided that allows the front move plate 106 to extend at different position, such as at least about 230 mm, from the retracted position.

In one embodiment, the spring loaded mechanism 302 includes a lever 306 and a plunger 308. The plunger 308 is biased toward the front move plate 106 by a spring (not shown). In this manner, the plunger 308 automatically engages the holes 304, 801, 803 when the front move plate 106 is in a predefined position, such as a retracted position or an extended position as shown in FIG. 3. The lever 306 is operable to move the plunger 308 against the bias of the spring, such that the plunger 308 is moved clear of the hole 304, thereby enabling the front move plate 106 to move along the front rack mount 104.

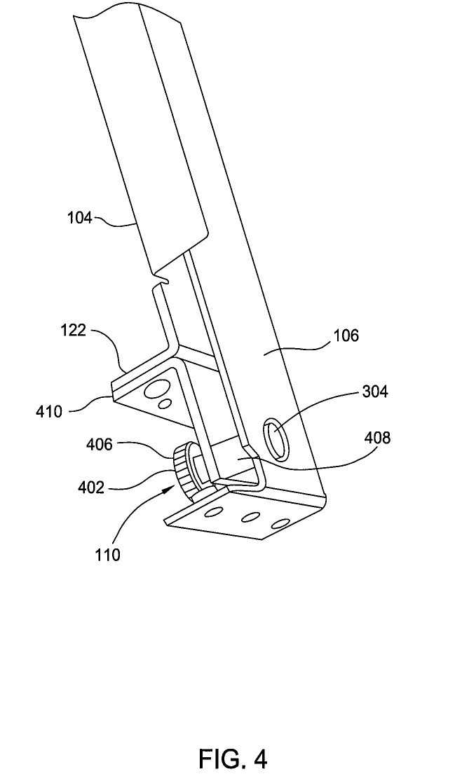

FIG. 4 depicts another embodiment of a lock assembly 110. In one embodiment, the lock assembly 110 is in the form of a spring loaded mechanism 402 coupled to the flange 122 of the front rack mount 104. A bracket 410 may be utilized to couple the spring loaded mechanism 402 to the flange 122. The spring loaded mechanism 402 generally includes a knob 406 and plunger 408 mounted to the bracket 410. The bracket 410 is coupled to the flange 122 of the front rack mount 104. The plunger 408 is biased by a spring (not shown) toward the front move plate 106. The knob 406 limits the travel of the plunger 408 into the hole 304. The knob 406 may be pulled to retract the plunger 408 from the hole 304, thereby allowing the front move plate 106 to slide freely along to the front rack mount 104. In one embodiment, the size of the lock assembly 110 may be configured to have a smaller size to facilitate operation for users.

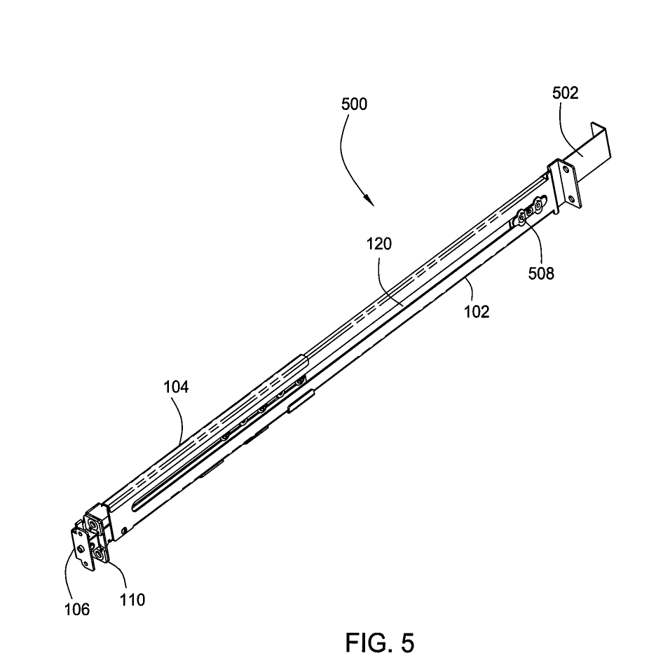

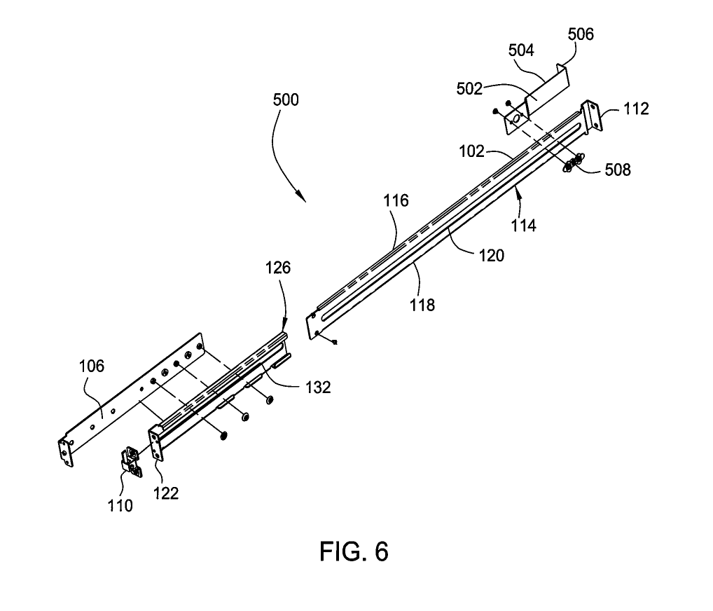

FIGS. 5 and 6 are assembled and exploded views of another embodiment of a slider mounting module 500. The slider mounting module 500 is generally similar to the slider mounting module 100 described above except wherein the slider module 500 includes a back move plate 502 which is movably coupled to the back rack mount 102 by a bearing assembly 508. The bearing assembly 508 is configured to travel within the slot 120 of the back rack mount 102, thereby enhancing the ease of movement of the back move plate 502 relative to the back rack mount 102.

Referring to FIG. 6, the back move plate 502 generally includes a bar 504 having an inward turned flange 506. The flange 506 may include one or more mounting holes to facilitate supporting the rear end of the sliding flat panel display and keyboard module, such as a KVM assembly, as further described below.

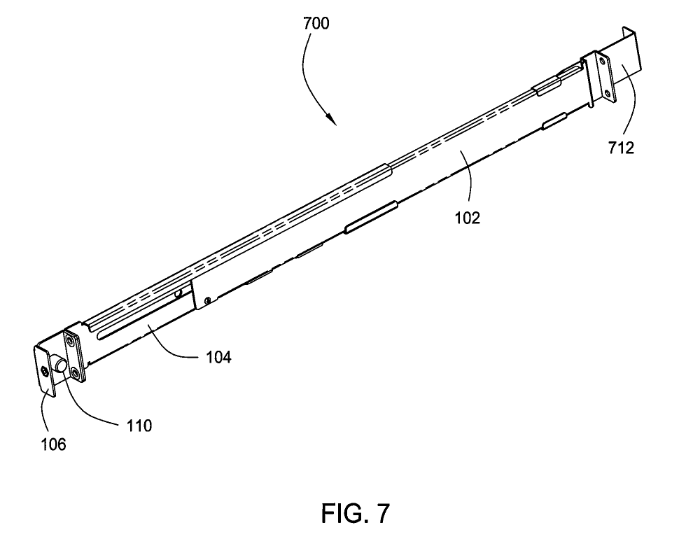

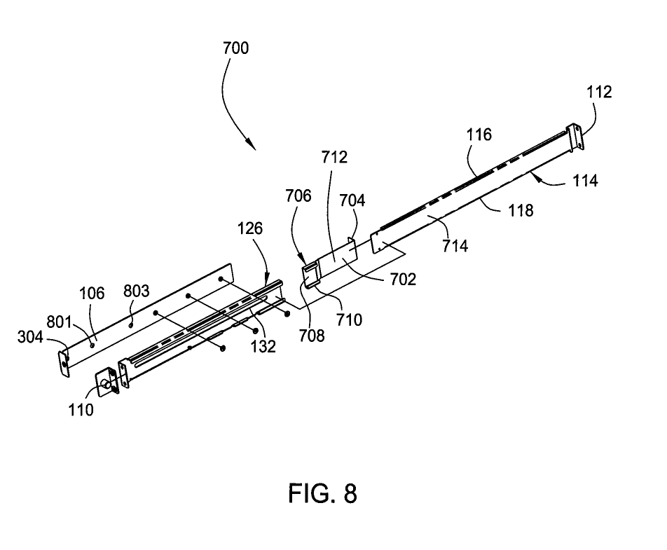

FIGS. 7 and 8 are isometric and exploded views of another embodiment of a slider mounting module 700. The slider mounting module 700 is configured substantially similar to the slider mounting modules described above except wherein the slider mounting module 700 includes a back rack mount 714 and a middle move plate 712 movably coupled to the back rack mount 714, as shown in FIG. 8, and the size of the lock assembly 110 is configured to have a smaller size to facilitate operation for users. The front move plate 106 includes one or more holes 304, 801, 803 to selectively engage with the lock assembly 110 to adjust the retraction and extension of the front move plate 106 relative to the front rack mount 104. In one embodiment, the lock assembly 110 may engage the first hole 304 to secure the front rack mount 104 at a retracted position. At least one of the holes 801, 803 is positioned to allow the front move plate 106 to extend to different positions from the retracted position by the engagement of the lock assembly 110 with the second hole 801 or the third hole 803. In the present embodiment, when the lock assembly 110 engages the hole 801, the front move plate 106 extends at least about 230 mm. Accordingly, when a display of a KVM switch system is mounted thereon, the extended front move plate 106 allows the display to be positioned further away from a server rack, as compared to conventional designs, thereby providing an increased range of motion for the display, such as up to greater than about 95 degrees, for example about 95 degrees to about 120 degrees, or 130 degrees or even greater, relative to the horizontal plane in which the front move plate 106 travels.

In one embodiment, the middle move plate 712 generally includes a bar 702 and a flange 704. The flange 704 generally has a perpendicular orientation relative to the bar 702. The flange 704 generally includes one or more holes for mounting the rear end of the sliding flat panel display and keyboard module.

The bar 702 of the middle move plate 712 additionally includes one or more retaining features 706. The retaining features 706 are generally configured to slideably retain the middle move plate 712 to the back rack mount 714 such that the middle move plate 712 may be positioned along the primary bar 114 of the back rack mount 714. In one embodiment, the retaining features 706 include at least one upper channel 708 and at least one lower channel 710 which respectively mate with the top and bottom edges 116, 118 of the primary bar 114 of the back rack mount 714, thereby allowing the back move plate 712 to be slid over the back rack mount 714 as the KVM assembly is moved within the server rack as further described below.

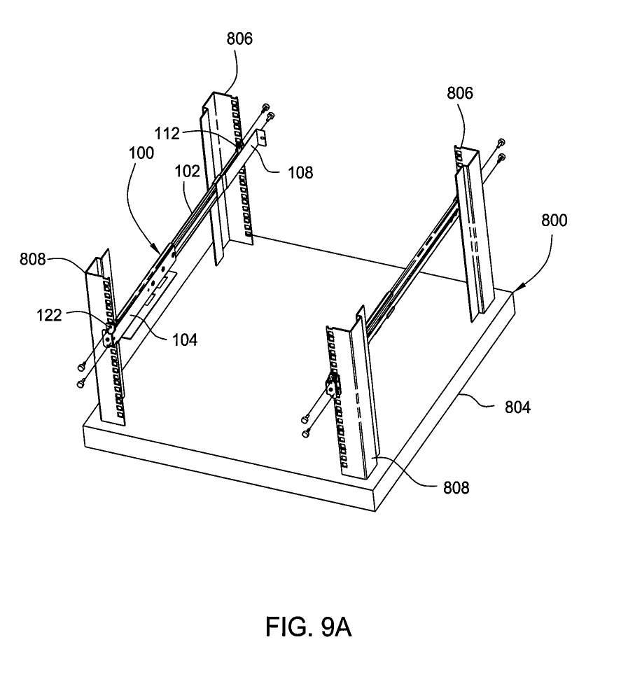

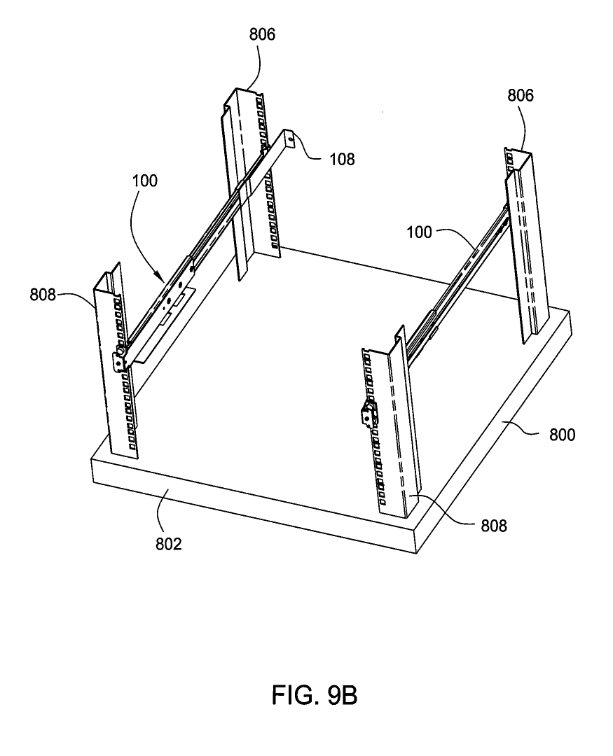

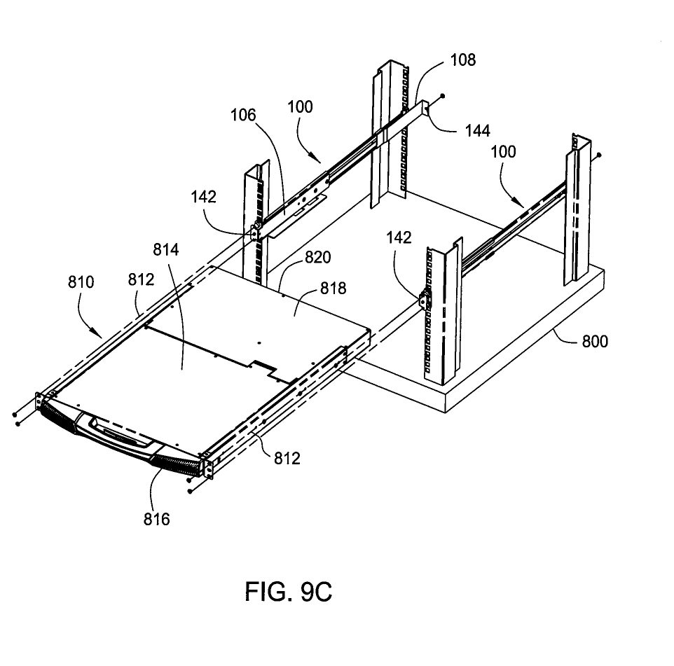

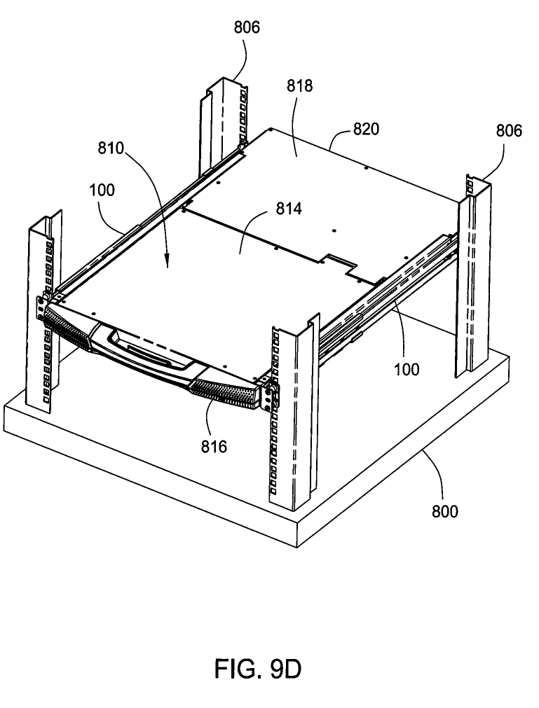

FIGS. 9A-D depict one embodiment of a slider mounting module 100 mounted to a server rack 800. Although the slider mounting module 100 is depicted in the embodiment described with reference to FIGS. 9A-D, it is contemplated that the other slider mounting modules are similarly utilized. Referring first to FIG. 9A, the server rack 800 includes a pair of back vertical supports 806 and a pair of front vertical supports 808. The server rack 800 may additionally include doors or side panels (not shown). The flanges 112, 122 of the slider mounting module 100 are fastened to the front and back vertical supports 806, 808. As the front rack mount 104 of the slider mounting module 100 is telescopically mounted to the back rack mount 102, the slider mounting module 100 may accommodate different server racks having various distances between the front and back vertical supports 806, 808. As shown in FIG. 9B, the back move plate 108 is free to slide beyond the back vertical supports 806 of the server rack 800, thereby allowing the slider mounting module 100 to accommodate a KVM switch, monitor and keyboard which have a greater depth than the server rack 800. Moreover, as the motion of the front and back move plates 106, 108 are decoupled prior to mounting of the KVM assembly or components thereof, the slider mounting module 100 may accommodate different size KVM assemblies even after the module 100 is installed in the server rack 800 without difficultly or need for additional components.

Referring now to FIGS. 9C-D, a KVM assembly 810 is coupled to the slider mounting module 100. In the embodiment depicted in FIG. 9C, the KVM assembly 810 is coupled to the flange 144 of the back move plate 108 and the flange 142 of the front move plate 106. As the back move plate 108 and the front move plate 106 may move independent of one another, the distances between the flanges 142, 144 may be adjusted to accommodate different KVM assemblies 810 having different dimensions without customization. Additionally, as referred above and as shown in FIG. 9D, with the KVM assembly 810 retracted within the server rack 800, the rear 820 of the KVM assembly 810 may extend beyond the rear vertical supports 806 of the server rack 800.

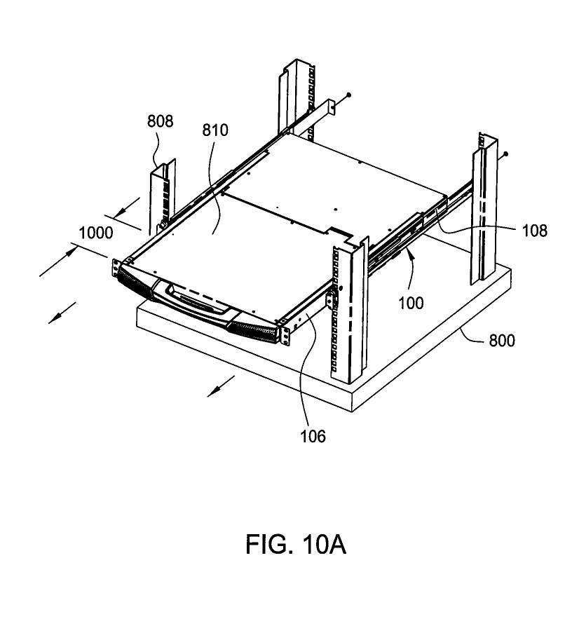

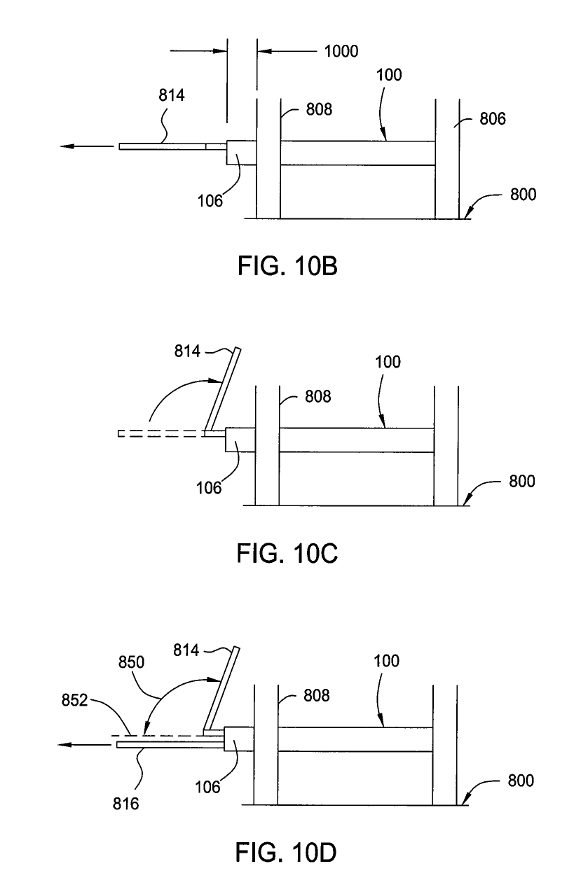

The KVM assembly 810 generally includes a keyboard 816 and monitor 814 coupled to a KVM switch 818 secured to a slider module 812. In the embodiment depicted in FIGS. 9A-D, the slider module 812 is configured as a dual slider module, as shown in FIG. 9C. The dual slider module 812 allows the keyboard 816 and monitor 814 to be independently extended and retracted. One embodiment of a dual slider module which may be adapted to benefit from the invention is provided in U.S. patent application Ser. No. 11/203,246, filed Aug. 25, 2005, which is incorporated by reference. It is contemplated that other slider mechanisms may be utilized to facilitate the extension and retraction of the keyboard 816 and monitor 814 from the front move plate 106. The monitor 814 and keyboard 816 will be more apparent with the description of FIGS. 10A-D which follows.

In operation, referring first to FIG. 10A, the lock assembly 110 is actuated such that the plunger 308 retracts from the hole 304 (as depicted in FIG. 3), thereby enabling the KVM assembly 810 to be pulled forward from the server rack 800 as the front move plate 106 and back move plate 108 slide forward along the slider mounting module 100. At a predefined extension 1000 from the front vertical supports 808 of the server rack 800, the plunger of the lock assembly 110 re-engages with the hole 801 or the hole 803 to secure the KVM assembly 810 in the extended position. The monitor 814 may then be extended using the dual slider module 812 as shown in FIG. 10B. The monitor 814 may then be rotated upward into a display position as shown in FIG. 10C. Due to the extension 1000 afforded by the slider mounting module 100, the viewing angle of the monitor 814 has a greater range as compared to conventional systems. In one embodiment, the monitor may be rotated at an angle 850 between about 0 and 180 degrees, such as greater than about 95 degrees, for example about 95 degrees and about 130 degrees, relative to a horizontal plane 852 defined by the KVM assembly 810. As shown in FIG. 10D, the keyboard 816 may be extended from the KVM assembly 810 using the dual slider module 812 to facilitate access to the keyboard.

While the foregoing is directed to embodiments of the present invention, other and further embodiments of the invention may be devised without departing from the basic scope thereof, and the scope thereof is determined by the claims that follow.

What is claimed is:

1. A slider mounting module suitable for mounting a KVM assembly to a server rack, the slider mounting module comprising:
a front rack mount;
a back rack mount slidably coupled to the front rack mount in a manner that allows a combined length of the rack mounts to be adjusted;
a front move plate slidably coupled to the front rack mount; and
a back move plate slidably coupled to the back rack mount.

2. The module of claim 1, wherein the back rack mount comprises:
a mounting flange and a primary bar.

3. The module of claim 2, wherein the primary bar comprises:
a top edge and a bottom edge configured to provide a bearing surface for the front rack mount coupled thereto; and
a slot configured to couple the back move plate to the back rack mount.

4. The module of claim 1, wherein the front rack mount comprises:
a mounting flange and a secondary bar.

5. The module of claim 4, wherein the secondary bar further comprises one or more retaining feature configured to retain the back rack mount and the front rack mount in a substantially aligned orientation.

6. The module of claim 4, wherein the secondary bar further comprises:
a second slot formed through the secondary bar and aligned with a first slot formed in a primary bar in the back rack mount.

7. The module of claim 1 further comprising:
a lock assembly coupled to the front rack mount configured to selectively retain the front move plate from moving relative to the front rack mount.

8. The module of claim 7, wherein the lock assembly further comprises:
a plunger biased toward the front move plate; and
a lever operable to move the plunger against the bias.

9. The module of claim 7, wherein the lock assembly further comprises:
a knob and a plunger mounted to a bracket, wherein the bracket is coupled to the front rack mount.

10. The module of claim 1 further comprising:
a middle move plate movably coupled to the back rack mount.

11. The module of claim 1, wherein the back move plate is coupled to the back rack mount by a bearing assembly.

12. A KVM switch system receiving assembly, comprising:
a server rack having a front support and a back support; and
a slider mounting assembly disposed to a space defined by the front and the back support of the server rack, wherein the slider mounting assembly comprises:
a front rack mount;
a back rack mount slidably coupled to the front rack mount in a manner that allows a combined length of the rack mounts to be adjusted;
a front move plate slidably coupled to the front rack mount; and
a back move plate slidably coupled to the back rack mount.

13. The assembly of claim 12, wherein the slider mounting assembly further comprises:
a middle move plate coupled to the back move plate.

14. The assembly of claim 12, wherein the back move plate is coupled to the back rack mount by a bearing assembly.

15. The assembly of claim 12, wherein the front rack mount is in an extended position relative to the front rack mount.

16. The assembly of claim 12 further comprising:
a KVM switch system having a first side coupled to the front move plate and a second side coupled to the back move plate.

17. The assembly of claim 16, wherein the KVM switch system further comprises:
a display portion disposed in the KVM system configured to be slidably extended outward from the server rack.

18. The assembly of claim 17, wherein the display portion is rotatable to a position having an angle greater than 95 degrees relatively to a horizontal plane.

19. A KVM switch system storage assembly, comprising:
a server rack having a front support and a back support;
a slider mounting assembly disposed to a space defined by the front and the back support of the server rack; and
a KVM switch system coupled to the server rack through the slider mounting assembly, wherein the KVM switch system includes a monitor display configured to be extendable outward from the server rack and rotatable to a position having an angle greater than 95 degrees relatively to a horizontal plane.
